(19) United States
(12) Patent Application Publication
(10) Pub. No.: US 2017/0092412 A1
(43) Pub. Date: Mar. 30, 2017

(54) PACKAGE INTEGRATED POWER INDUCTORS USING LITHOGRAPHICALLY DEFINED VIAS

(71) Applicants: Mathew J. Manusharow, Phoenix, AZ (US); Yonggang Li, Chandler, AZ (US); William J. Lambert, Chandler, AZ (US); Krishna Bharath, Chandler, AZ (US); Adel A. Elsherbini, Chandler, AZ (US); Feras Eid, Chandler, AZ (US); Aleksandar Aleksov, Chandler, AZ (US); Henning Braunisch, Phoenix, AZ (US)

(72) Inventors: Mathew J. Manusharow, Phoenix, AZ (US); Yonggang Li, Chandler, AZ (US); William J. Lambert, Chandler, AZ (US); Krishna Bharath, Chandler, AZ (US); Adel A. Elsherbini, Chandler, AZ (US); Feras Eid, Chandler, AZ (US); Aleksandar Aleksov, Chandler, AZ (US); Henning Braunisch, Phoenix, AZ (US)

(21) Appl. No.: 14/866,852

(22) Filed: Sep. 26, 2015

(51) Int. Cl. H01F 27/28; H01F 41/04; H01F 27/24

(52) U.S. Cl. CPC H01F 27/2804; H01F 27/24; H01F 41/041; H01F 2027/2809

(57) ABSTRACT

Embodiments of the invention include inductors integrated into a package substrate that have increased thicknesses due to the use of shaped vias, and methods of forming such packages. In an embodiment of the invention an inductor may be formed in a package substrate may include a first inductor line formed on the package substrate. In some embodiments, a shaped via may be formed over the first inductor line. Additional embodiments may include a dielectric layer that is formed over the package substrate, the first inductor line and around the shaped via. In one embodiment, a second inductor line may also be formed over the shaped via. Some embodiments of the invention may include an inductor that is a spiral inductor.

### FIELD OF THE INVENTION

Embodiments generally relate to packaging for electronic devices. More specifically, embodiments relate to packaging solutions that include inductors formed with shaped vias.

### BACKGROUND OF THE INVENTION

Scaling of any analog circuit from one silicon node generation to the next generation presents several problems. One such problem relates to the use of fully integrated voltage regulators (FIVRs) for power management in semiconductor dies. In a FIVR device, one or more air core inductors (ACIs) for voltage regulation may be packaged with the semiconductor die. Typically, the inductors are located on a backside of the package that is opposite to the side on which the semiconductor die is packaged. The ACI may be electrically coupled through the package to a capacitor on the semiconductor die. However, the drive to smaller scaling that is present with each successive generation of devices decreases the area available for the inductors. As the area allotted for the ACIs continues to shrink, crowding induces higher resistive losses in the ACIs and reduces the overall power delivery network's efficiency.

Accordingly, there is a need to form improved ACIs that reduce the resistive losses and improve voltage conversion efficiency.

### BRIEF DESCRIPTION OF THE DRAWINGS

FIG. 1A is a plan view and a corresponding cross-sectional illustration of a dielectric layer with a seed layer formed over the surface, according to an embodiment of the invention.

FIG. 1B is a plan view and a corresponding cross-sectional illustration of the device after a lower inductor line has been formed over the surface, according to an embodiment of the invention.

FIG. 1C is a plan view and a corresponding cross-sectional illustration of the device after a second photoresist material has been deposited and patterned to allow for a shaped via to be formed along the lower inductor line, according to an embodiment of the invention.

FIG. 1D is a plan view and a corresponding cross-sectional illustration of the device after the second photoresist material and the exposed portions of the seed layer have been removed, according to an embodiment of the invention.

FIG. 1E is a plan view and a corresponding cross-sectional illustration of the device after a second dielectric layer has been formed over the surface, according to an embodiment of the invention.

FIG. 1F is a plan view and a corresponding cross-sectional illustration of the device after a seed layer has been formed over the second dielectric layer, according to an embodiment of the invention.

FIG. 1G is a plan view and a corresponding cross-sectional illustration of the device after a third photoresist material has been deposited and patterned to form an upper inductor line over the shaped via, according to an embodiment of the invention.

FIG. 1H is a plan view and a corresponding cross-sectional illustration of the device after the third photoresist layer and the second seed layer have been removed, according to an embodiment of the invention.

FIG. 2 is a plan view and a corresponding cross-sectional illustration of an air core inductor with multiple turns in a single layer, according to an embodiment of the invention.

FIG. 3A is a cross-sectional view of a packaged device that includes an inductor and a connection from the semiconductor die to the power plane with conventional vias, according to an embodiment of the invention.

FIG. 3B is a partial plan view of the conventional vias coupled to the power plane, according to an embodiment of the invention.

FIG. 4A is a cross-sectional view of a packaged device that includes an inductor and a connection from the semiconductor die to the power plane with a shaped via, according to an embodiment of the invention.

FIG. 4B is a partial plan view of the shaped via coupled to the power plane, according to an embodiment of the invention.

FIG. 5 is an illustration of a schematic block diagram of a computer system that utilizes a semiconductor package, according to an embodiment of the invention.

### DETAILED DESCRIPTION OF THE INVENTION

Described herein are systems that include lithographically defined shaped vias for various power management applications. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order to not obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

One of the main drivers for package design rules is the input/output (I/O) density per mm per layer (IO/mm/layer). The I/O density may be limited by the via pad sizes. However, current packaging technologies limit the extent to which the size of the via pads may be reduced. The via pads need to be relatively large due to the laser drilling process used to create the via openings through a dielectric layer above the via pads. Laser drilling is limited by the minimum feature size and the misalignment of the laser when drilling the via opening. For example, the minimum feature size of a laser drilled via opening may be approximately 40 μm or larger when a CO₂ laser is used, and the misalignment between the layers may be approximately +/−15 μm or larger. As such, the via pad sizes may need to be approximately 70 μm (i.e., 40+2(15) μm) or larger. Alternative laser sources, such as UV lasers, may be able to reduce the via opening more, but throughput is also greatly decreased. Accordingly, embodiments of the invention may utilize one or more processes that form the vias with lithographic processes instead of with lasers. The use of lithographic processes allows for an improved layer-to-layer alignment and smaller pads compared to laser drilling, which in turn results in higher I/O densities. Additionally, the throughput time is deceased with lithography-based processes because all of the vias may be formed at once (i.e., a single exposure and patterning) instead of being formed sequentially when laser drilling is used.

Furthermore, the use of lithography-based processes to form the vias allows for the vias to be formed in any desire shape. Instead of being limited to the shape of the laser, a lithographically defined via may be customized for a desired purpose. For example, whereas a laser defined via may be limited to a circular shape, embodiments of the invention may include vias that are rectangular in shape and extend in lateral direction along the routing line. Instead of electrically coupling two routing lines formed on different layers of a package substrate with a geometry restricted via produced with laser drilling, embodiments of the invention may allow for a shaped via to extend through the package substrate a length substantially equal to the length of the two routing lines. Accordingly, the use of shaped vias may allow for a routing line to be formed that has a thickness equal to the combined thicknesses of the two routing lines plus the distance between the two routing lines. Increasing the thickness of a routing line has various benefits.

In one embodiment, the thicker routing line may be used to form an ACI. In such an embodiment, a shaped via may be used to couple a lower inductor line to an upper inductor line. As such, the cross-sectional area of the ACI lines can be greatly increased. The increased cross-sectional area of the inductor line significantly improves the DC resistance (RDC) of the ACI, a key parameter in determining FIVR efficiency. In some embodiments, the use of a shaped via increases the cross-sectional area of the ACI by a factor of 1.5 or more compared to standard microvias, depending the thickness of the shaped via. In such embodiments, the increase in the cross-sectional area may reduce RDC by between approximately 30-50%. In some embodiments, the use of shaped vias to increase the cross-sectional area of the ACI may also reduce the AC resistance (RAC) and increase the quality factor Q of the inductor.

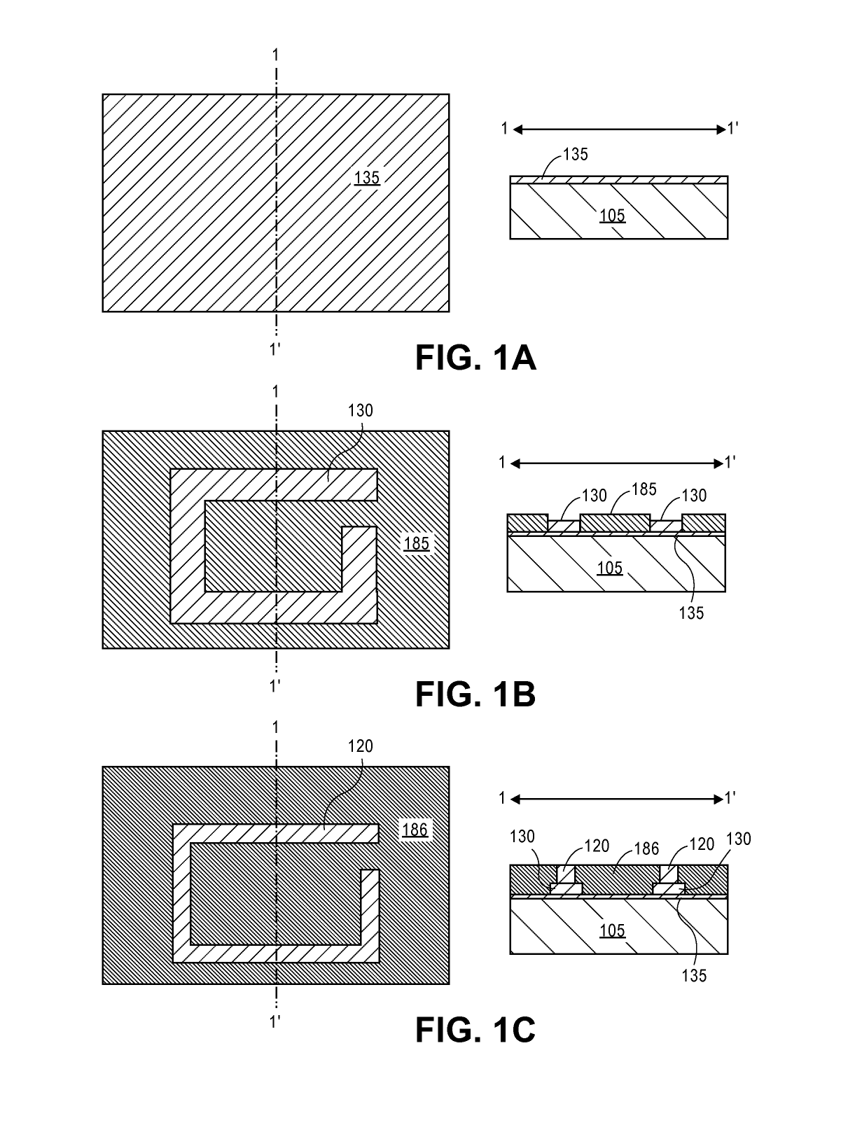

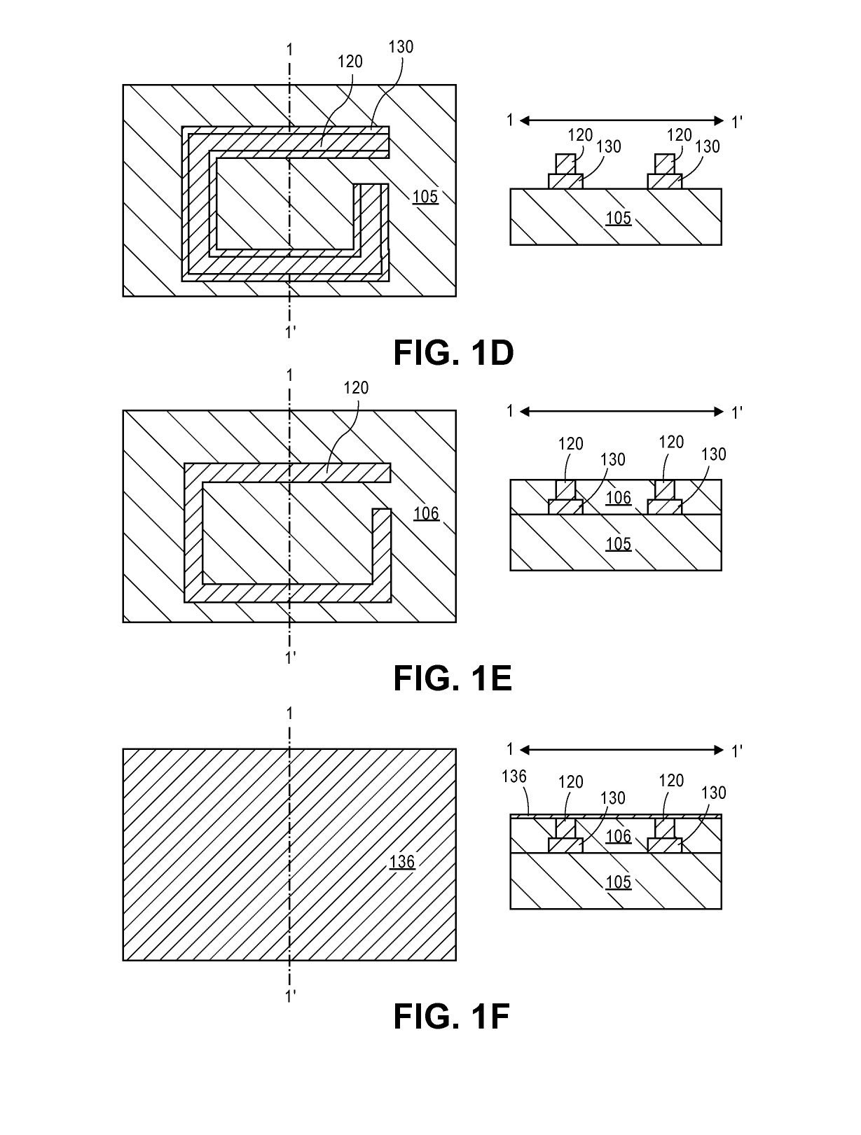

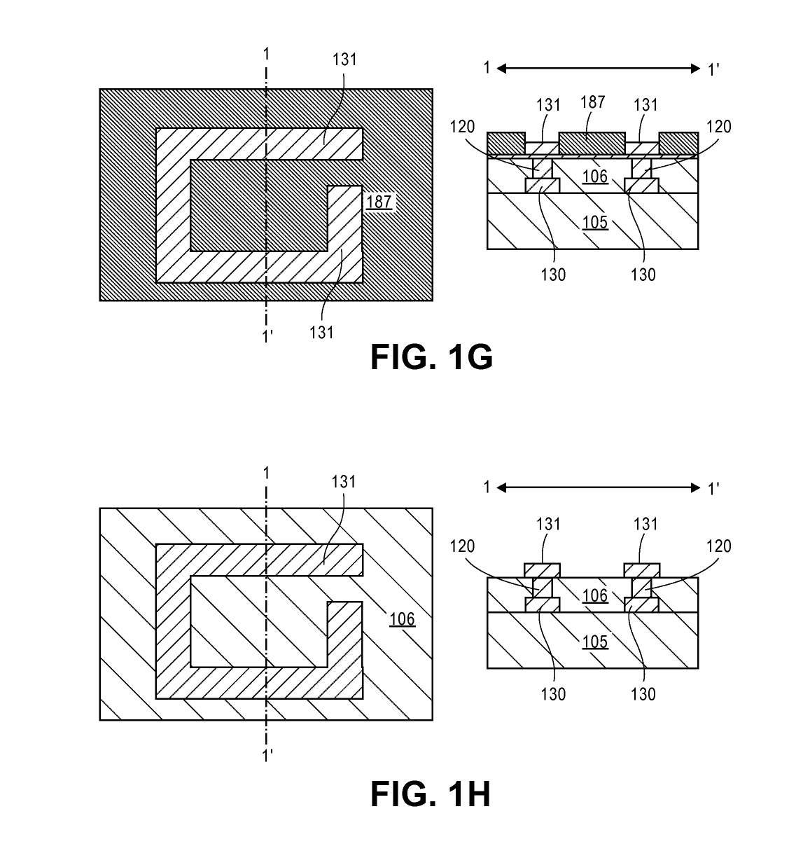

According to an embodiment, an inductor with an increased cross-sectional area formed with shaped vias may be formed with a suitable lithography or laser patterning process. One such embodiment that utilizes a lithography process is illustrated and described with respect to FIGS. 1A-1H. FIGS. 1A-1H each include plan view illustrations and corresponding cross-sectional views along line 1-1′. In the illustrated embodiment, only the formation of ACI is shown, however it is to be appreciated that additional features, such as vias, pads, and/or transmission lines, may be formed at the same time and with the same processing operations, according to embodiments of the invention.

Referring now to FIG. 1A, embodiments of the invention may include a seed layer 135 that is deposited over a top surface of a dielectric layer 105. By way of example, the dielectric layer 105 may be a polymer material, such as, for example, polyimide, epoxy or build-up film (BF). In an embodiment, the dielectric layer 105 may be one layer in a stack that includes a plurality of dielectric layers used to form a build-up structure. As such, the dielectric layer 105 may be formed over another dielectric layer. Additional embodiments may include forming the dielectric layer 105 as the first dielectric layer over a core material on which the stack is formed. In an embodiment, the seed layer 135 may be a copper seed layer. According to an additional embodiment, the layer 105 may be the bottommost layer of a package, and be a metallic material. In such embodiments, the seed layer 135 may be omitted.

Referring now to FIG. 1B, a photoresist material 185 may be formed over the seed layer 135 and patterned to provide openings for the formation of a lower inductor line 130. According to an embodiment, the patterning of the photoresist material 185 may be implemented with lithographic processes (e.g., exposed with a radiation source through a mask (not shown) and developed with a developer). After the photoresist material 185 has been patterned, the lower inductor line 130 may be formed. In an embodiment, the lower inductor line 130 may be formed with an electroplating process or the like.

According to an embodiment, the lower inductor line 130 may be any desired shape used for an ACI. For example, the illustrated embodiment depicts a lower inductor line 130 that forms a single loop. It is to be appreciated that that the width of the lower inductor line 130 and/or the diameter of the loop may be varied to provide an ACI with desired characteristics (e.g., inductance, resistance and quality factor). The illustrated embodiment includes a loop that is substantially rectangular, but embodiments are not limited to such configurations. The use of lithographic patterning allows for flexibility in the shape of the loop. Accordingly, any desired shape may be chosen for the lower inductor line 130.

Referring now to FIG. 1C, the first photoresist material 185 is stripped, and a second photoresist material 186 is deposited over the lower inductor line 130. A shaped via opening may then be patterned into the second photoresist material 186 by exposing the second photoresist material 186 to radiation through a via layer mask (not shown) and developing with a developer. According to an embodiment, the shaped via 120 may be formed in the shaped via opening. According to an embodiment, the shaped via 120 may be formed with any suitable deposition process, such as electroplating or the like.

As illustrated in the plan view in FIG. 1C, the shaped via 120 is substantially the same length as the underlying lower inductor line 130. However, additional embodiments are not limited to such configurations, and the shaped via 120 may be formed over selected regions of the lower inductor line 130. Furthermore, as illustrated in the cross-sectional view along line 1-1′, embodiments of the invention may include a shaped via 120 that is not the same width as the lower inductor line 130. Such embodiments may allow for some misalignment between the lower inductor line 130 and the shaped via 120. Though the illustrated embodiment depicts a difference in the widths of the lower inductor line 130 and the shaped via 120, it is to be appreciated that embodiments of the invention may also include a shaped via 120 that is self-aligned on the lower inductor line 130, and therefore may be formed with substantially similar widths. In such an embodiment, there may be no discernable difference between the width of the lower inductor line 130 and the shaped via 120.

Referring now to FIG. 1D, the second photoresist material 186 is stripped and the remaining portions of the seed layer 135 are removed. According to an embodiment, the seed layer 135 may be removed with a seed etching process. As shown in the illustrated embodiment, the shaped via 120 is formed prior to the formation of a second dielectric layer. Such embodiments of the invention may be referred to as a via first lithography process.

Referring now to FIG. 1E, a second dielectric layer 106 is formed over the exposed shaped via 120 and lower inductor line 130. According to an embodiment the second dielectric layer 106 may be formed with any suitable process, such as lamination or slit coating and curing. In an embodiment, the second dielectric layer 106 is formed to a thickness that will completely cover a top surface of the shaped via 120. As opposed to layer formation on crystalline structures (e.g., silicon substrates), each of the dielectric layers may not be highly uniform. Accordingly, the second dielectric layer 106 may be formed to a thickness that is greater than the shaped via 120 to ensure that the proper thickness is reached across the entire substrate. When the second dielectric is formed above the shaped via, a controlled etching process may then be used to expose the top surface of the shaped via 120, as illustrated in FIG. 1E.

In an embodiment, the dielectric removal process may include a wet etch, a dry etch (e.g., a plasma etch), a wet blast, or a laser ablation (e.g., by using excimer laser). According to an additional embodiment, the depth controlled dielectric removal process may be performed only proximate to the shaped via 120. For example, laser ablation of the second dielectric layer 106 may be localized proximate to the location of the via 120. In some embodiments, the thickness of the second dielectric layer 106 may be minimized in order to reduce the etching time required to expose the shaped via 120. In other embodiments, when the thickness of the dielectric can be well controlled, the shaped via 120 may extend above the top surface of the second dielectric layer 106 and the controlled dielectric removal process may be omitted.

Referring now to FIG. 1F, a second seed layer 136 may be formed over the exposed portions of the second dielectric layer 106. According to an embodiment of the invention, the second seed layer 136 is a seed layer suitable for use in growing conductive features on the surface of the second dielectric layer 106. For example, the second seed layer 136 may be a copper seed layer.

Referring now to FIG. 1G, a third photoresist material 187 is deposited and patterned to form openings for the a second level of conductive features, such as an upper inductor line 131. According to an embodiment, the next level of conductive features may then be formed in the openings with a suitable process, such as electroplating or the like.

After the formation of the upper inductor line 131 on the second dielectric layer 106, the third photoresist material 187 may be removed and the second seed layer 136 may be etched away with a seed etching process, as illustrated in FIG. 1H. According to an embodiment, the upper inductor line 131 formed on the second dielectric layer 106 may be substantially similar to the lower inductor line 130 formed on the first dielectric layer 105. As such, the upper inductor line 131 may have a width that is greater than the width of the shaped via 120. According to an additional embodiment, the upper inductor line 131 may be omitted.

The illustrated embodiment includes a single layer with a shaped via 120, though embodiments are not limited to such configurations. For example, the processing operations described above may be repeated one or more times in order to form a plurality of shaped via layers. Accordingly, the thickness of the inductor may be any desired thickness, up to the entire thickness of the package substrate. In the process flow described above with respect to FIGS. 1A-1H, the shaped via 120 was formed and then a second dielectric layer 106 was formed around the shaped via 120. However, embodiments are not limited to such configurations. For example, the second dielectric layer 106 may be formed first and openings may be patterned into the second dielectric layer to form the shaped via, according to additional embodiments of the invention.

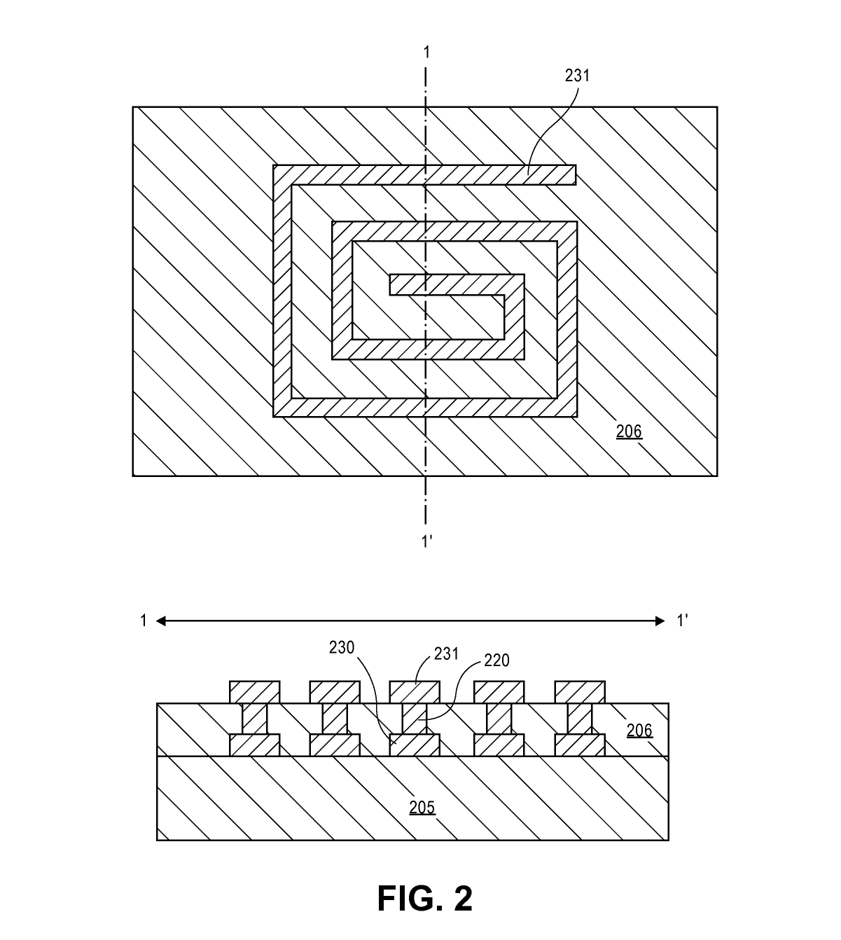

Additionally, embodiments of the invention are not limited to an inductor with a single turn, and multi-turn (also referred to as spiral) inductors may also be formed with a shaped via connecting the lower inductor line to the upper inductor line. Such an embodiment is illustrated in FIG. 2. FIG. 2 provides a plan view and corresponding cross-sectional view of a spiral inductor, according to an embodiment of the invention. In the plan view, the upper inductor layer 231 is visible over the second dielectric layer 206. As illustrated, three loops are present, though embodiments may also include more than three loops or fewer than three loops. In the cross-sectional view along line 1-1′ the shaped via 220 and the lower inductor line 230 are visible. The formation of the spiral inductor illustrated in FIG. 2 may be formed with substantially the same processing operations described above with respect to FIGS. 1A-1H. The use of lithographic patterning to form the shaped via 220 makes the inclusion of multiple loops trivial since all that is needed is a change to the exposure masks used to pattern the lower inductor line 230, the shaped via 220, and the upper inductor line 231.

While the inductors described herein are referred to air core inductors, it is to be appreciated that additional embodiments of the invention may also use inductors that include materials other than air gaps. For example, any inductor may be fabricated according to a process similar to the one described above with respect to FIGS. 1A-1H with the exception that the material used as the core within the inductor is a material that has a relative permeability is close to 1.0 H. Such an inductor with a core material that has a relative permeability close to 1.0 H may also be referred to as an ACI. Additionally, an ACI may be substituted with a magnetic inductor that includes any suitable magnetic nanoparticle materials that could be combined with the dielectric material. The formation of such an inductor may be substantially similar to the formation of an ACI with the exception that the core material may be different. Embodiments may also include multi-layer magnetic inductors.

Furthermore, while a single inductor layer is disclosed in FIGS. 1A-1H, it is to be appreciated that a plurality of inductor layers may be formed in the package substrate. In an exemplary embodiment, an eight layer package may include an ACI that is fabricated in the bottom most four layers of the package. A first turn of the inductor may include traces on the first and second layers, formed in parallel, and the second turn of the inductor may include traces on the third and fourth layers, also formed in parallel. In an embodiment, a first shaped via may then be located between the traces on the first and second layers, and a second shaped via may be formed between the traces on the third and fourth layers. Additionally, a shaped via from the first and second layer to third and fourth layer may be placed only at the layer transition.

Other manufacturing technologies exist to make similar shaped vias. In an embodiment, the shaped via opening may be drilled using a reactive ion etching (RIE) process that etches through a photoresist layer or a hard mask layer. Additionally, the shaped via openings may be drilled with a line shaped laser beam. For example, the laser beam may be shaped either optically or mechanically. The shaped laser beam may be steered and positioned (e.g., with a scanning system) to target locations where a shaped via opening is desired. According to an embodiment, the laser may be a pulsed CO₂ laser or a Q-switched ultra-violet (UV) laser. Embodiments may use the UV laser when relatively small shaped via dimensions are needed.

Another embodiment may use a laser beam to scan over a mask which has the shaped via pattern and is projected to the work piece. The fluence of the laser on the work piece may be sufficiently high to ablate the dielectric material and form the shaped via opening. By way of example, the lasers in such an embodiment may include Q-switched solid state UV lasers and excimer lasers. In embodiments that use either of the two previously described laser patterning processes to form the via openings, a photosensitive dielectric is not needed since the lasers themselves ablate the dielectric material and no exposure and developing processes are required.

Yet another embodiment of the invention may include forming the shaped via opening with a process that uses of a photosensitive dielectric. In such an embodiment, the photosensitive dielectric may be lithographically patterned and developed to form the shaped via openings. According to some embodiments, a post patterning cleaning process may also be included after the shaped via openings are formed. Embodiments may then include forming the shaped via in the opening with a metallization process, such as a semi-additive process (SAP).

Those skilled in the art will recognize that the inclusion of the shaped vias to increase the thickness of the inductor provides benefits to the RDC, RAC, and quality factor Q of the inductor that are not provided when microvias are used. For example, when a lower inductor line 130 and an upper inductor line 131 are coupled together by a plurality of microvias formed between the two lines, the same benefits are not seen. For example, it may be argued that by placing a large number of micro-vias between the lower inductor line 130 and the upper inductor line 131 along the length of the loop may result in a similar benefit since there is an increased cross-sectional area along portions of the inductor. However, this is not the case.

There is no significant improvement in the RDC, RAC, or Q when such a micro-via array is used, because the additional microvias do not actually increase the effective thickness of the inductor since the current is flowing laterally along the inductor. Instead, the lower inductor layer 130 and upper inductor layer 131 are equi-potential at each point where a microvias is formed between them, because they are electrically coupled together at the two ends of the inductor. Since the lower inductor layer 130 and upper inductor layer 131 do not have a voltage potential difference at each point where a microvias is formed, no current flows through the additional micro-vias. In contrast, the shaped via 120 effectively increases the thickness of the inductor because it runs continuously along the length of the inductor.

Accordingly, embodiments of the invention that include a via line 120 between the lower inductor layer 130 and upper inductor layer 131 may reduce the RAC by as much as 15% or more compared to a traditional micro-via based design. Additionally, embodiments of the invention that include a via line 120 between the lower inductor layer 130 and upper inductor layer 131 may reduce the RDC by as much as 50% or more compared to a traditional micro-via based design. Also, embodiments of the invention that include a via line 120 between the lower inductor layer 130 and upper inductor layer 131 may increase the Q-factor by as much as 20% or more compared to a traditional micro-via based design.

In addition to improving the quality factor Q of ACIs, embodiments of the invention may also use shaped vias to meet Imax current limits. The Imax current limit is the maximum amount of current that can pass through a via or plane without greatly enhancing the probability that the device will fail. According to an embodiment, the use of a shaped via improves the short-term and long-term reliability of the ACI structure when exposed to high currents by lowering the maximum current density in both the vias and planes. As such, the risk of exceeding the Imax current limit is reduced.

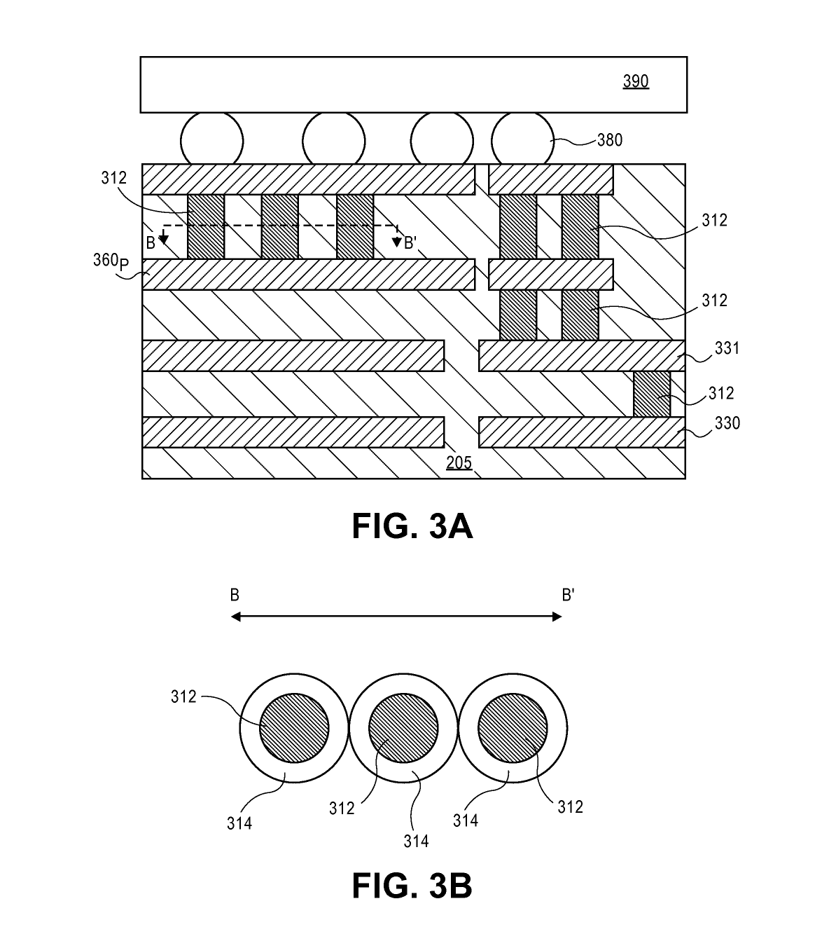

A schematic cross-sectional illustration of a packaged device that utilizes microvias to provide current to the ACIs is illustrated in FIG. 3A. In the illustrated embodiment, a semiconductor die 390 may be packaged on a package substrate 305. For example, the semiconductor die 390 may be flip-chip bonded to the package substrate 305 with a plurality of solder bumps 380. The solder bumps 380 may electrically couple semiconductor chip to a power plane 360p in the package substrate 305 and to an ACI formed by lines 330, 331, and via 312. In order to provide the proper power, each ACI requires a current of approximately 3 A. However, supplying this much current with microvias produces several issues.

Since the microvias 312 are currently formed with laser drilling operations, the maximum size of each microvia is limited. As such, the current that can flow through each of the microvias 312 is also limited. In order to meet the Imax current limit, three or more microvias 312 may need to be formed between the power plane 360_{P} and the semiconductor die 390. Additionally, even when a sufficient number of microvias 312 are formed, each microvia may transmit a different amount of current due to variations in placement and size of the microvias 312 (attributable to the variability in the laser drilling process). Accordingly, misaligned microvias 312 may result in a current spike through one or more of the microvias 312 that could damage the device.

Furthermore, the misalignment and size requirements require a substantial amount of area on the routing layers. FIG. 3B is a partial plan view that of the microvias 312 formed over via pads 314 on the power plane (not shown in FIG. 3B). Due to the misalignment present in laser drilling operations the via pads 314 need to be significantly larger than the diameter of the via drill. For example, an approximately 75 μm or greater pad diameter may be needed to allow for an approximately 50 μm microvia 312 to be formed over the via pads 314. Accordingly, the area allotted for the microvias 312 may only account for approximately 60% or less of the via pad area 314.

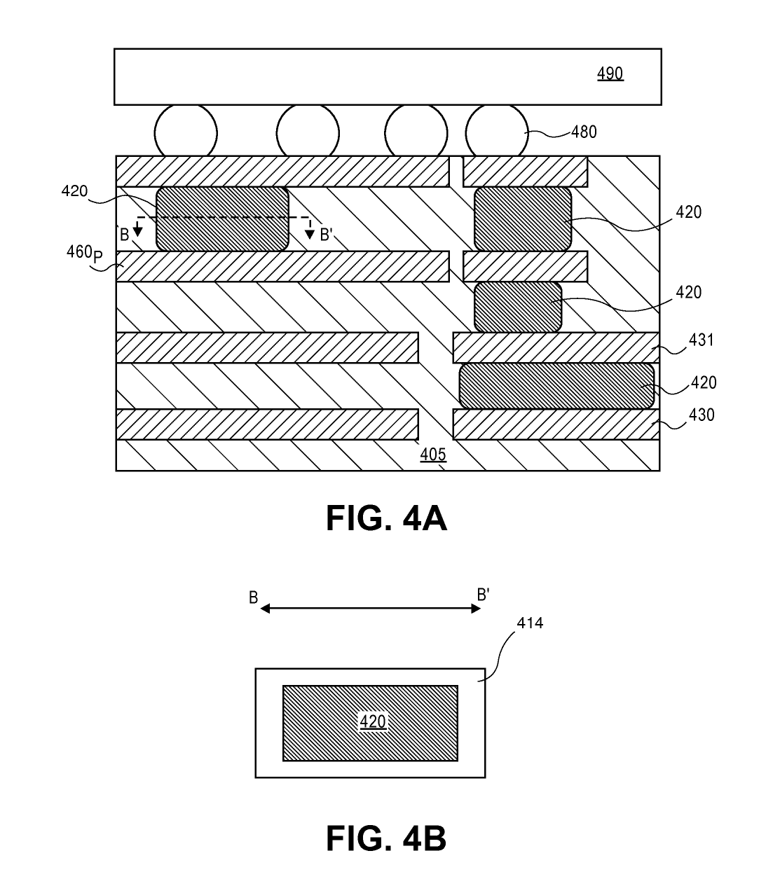

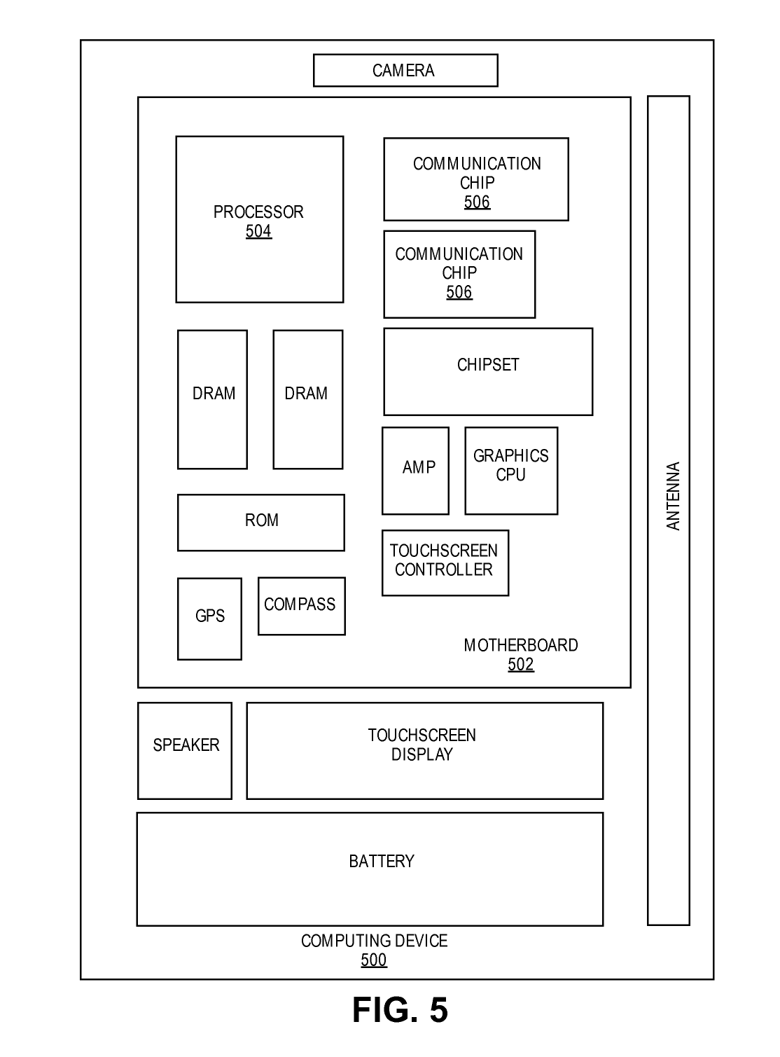

In contrast, embodiments of the invention may utilize a shaped via to provide the power to the semiconductor die and the ACI. Such an embodiment is illustrated in the cross-sectional illustration view shown in FIG. 4A. As illustrated, the power plane 360_{P} is coupled to the semiconductor die 490 by a single shaped via 420. The use of a single shaped via 420 allows for all of the current to flow through a single path. As such, there is no possibility of the uneven current distribution that may be present when multiple microvias are used, as described above.

In the partial plan view illustrated in FIG. 4B, the increase in utilization of the via pad 414 is illustrated. According to an embodiment, the savings in area, compared to devices that use microvias to supply the same amount of current, is almost 40%. Accordingly, embodiments of the invention allow for Imax targets to be met in a much smaller area. While the plan view illustrates the use of a via line to electrically couple the power plane 460_{P} to the semiconductor die 490, it is to be appreciated that via lines 420 may be used to electrically couple any conductive layers that are formed on different layers of the package substrate. For example, in FIG. 4A, several alternating layers of conductive lines and shaped vias provide a connection from the inductor (i.e., lower inductor line 430, via line 420, and upper inductor line 431) to the semiconductor die 490 through the package substrate 405. Accordingly, the via lines allow for a reduced footprint for each of the via paths between conductive lines, thereby allowing for improved scaling capabilities.

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die may be packaged with one or more devices on a package substrate that includes a thermally stable RFIC and antenna for use with wireless communications, in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be packaged with one or more devices on a package substrate that includes one or more an inductor with a shaped via such as those described herein, in accordance with various embodiments of the invention.

The following examples pertain to further embodiments. The various features of the different embodiments may be variously combined with some features included and others excluded to suit a variety of different applications.

Some embodiments of the invention include an inductor formed in a package substrate comprising: a first inductor line formed on the package substrate; a shaped via formed over the first inductor line; and a dielectric layer formed over the package substrate, the first inductor line and around the shaped via.

Additional embodiments of the invention include an inductor, wherein the inductor is a spiral inductor.

Additional embodiments of the invention include an inductor, wherein the shaped via has a width that is less than a width of the first inductor line.

Additional embodiments of the invention include an inductor, wherein the shaped via has a width that is substantially equal to a width of the first inductor line.

Additional embodiments of the invention include an inductor, further comprising a second inductor line formed over the shaped via.

Additional embodiments of the invention include an inductor, wherein the inductor further comprises a second shaped via formed over the second inductor line.

Additional embodiments of the invention include an inductor, wherein the dielectric layer is a photosensitive dielectric layer.

Additional embodiments of the invention include an inductor, wherein the inductor is an air core inductor (ACI).

Additional embodiments of the invention include an inductor, wherein the ACI includes a core material that has a permeability close to 1.0 H.

Additional embodiments of the invention include an inductor, wherein the inductor has a dielectric core that includes magnetic nano particles.

Additional embodiments of the invention include an inductor, wherein the inductor is electrically coupled to a capacitor by at least one shaped via that is not part of the inductor.

Additional embodiments of the invention include an inductor, wherein the capacitor is formed on a semiconductor die mounted to the package substrate, and wherein the inductor is a component in a fully integrated voltage regulator (FIVR).

Some embodiments of the invention include a method of forming an inductor in a package substrate, comprising: forming a first inductor line over a first dielectric layer; depositing a photoresist layer over the first dielectric layer and the first inductor line; patterning the photoresist layer to form a shaped via opening that extends along the length of the first inductor line; depositing a conductive material into the shaped via opening to form a shaped via over the first inductor line; removing the photoresist layer; forming a second dielectric layer over the first dielectric layer, the first inductor line, and the shaped via, wherein a top surface of the second dielectric layer is formed above a top surface of the shaped via; and recessing the second dielectric layer to expose a top portion of the shaped via.

Additional embodiments of the invention include a method, wherein the inductor is a spiral inductor.

Additional embodiments of the invention include a method, wherein the shaped via has a width that is less than a width of the first inductor line.

Additional embodiments of the invention include a method, wherein the shaped via has a width that is substantially equal to a width of the first inductor line.

Additional embodiments of the invention include a method, further comprising: forming a second inductor line over the shaped via.

Additional embodiments of the invention include a method, wherein recessing the second dielectric layer includes a wet etch, a dry etch, a wet blast, or a laser ablation process.

Additional embodiments of the invention include a method, wherein the recessing is a laser ablation process, and wherein the recessing is only implemented proximate to the shaped via.

Some embodiments of the invention include an air core inductor (ACI) formed in a package substrate comprising: a first inductor line formed on the package substrate, wherein the first inductor line includes a plurality of turns; a shaped via formed over the first inductor line; a dielectric layer formed over the package substrate, the first inductor line and around the shaped via; a second inductor line formed over the shaped via; and a capacitor electrically coupled to the inductor, wherein the capacitor is formed on a semiconductor die mounted to the package substrate.

Additional embodiments of the invention include an ACI, wherein the inductor is a component in a fully integrated voltage regulator (FIVR).

Additional embodiments of the invention include an ACI, wherein the inductor is electrically coupled to the capacitor by at least one shaped via that is not part of the inductor.

Additional embodiments of the invention include an ACI, wherein the dielectric layer is a photosensitive dielectric layer.

Additional embodiments of the invention include an ACI, wherein the shaped via has a width that is less than a width of the first inductor line.

Additional embodiments of the invention include an ACI, wherein the shaped via has a width that is substantially equal to a width of the first inductor line.

What is claimed is:

1. An inductor formed in a package substrate comprising:
a first inductor line formed on the package substrate;
a shaped via formed over the first inductor line; and
a dielectric layer formed over the package substrate, the first inductor line and around the shaped via.

2. The inductor of claim 1, wherein the inductor is a spiral inductor.

3. The inductor of claim 1, wherein the shaped via has a width that is less than a width of the first inductor line.

4. The inductor of claim 1, wherein the shaped via has a width that is substantially equal to a width of the first inductor line.

5. The inductor of claim 1, further comprising a second inductor line formed over the shaped via.

6. The inductor of claim 5, wherein the inductor further comprises a second shaped via formed over the second inductor line.

7. The inductor of claim 1, wherein the dielectric layer is a photosensitive dielectric layer.

8. The inductor of claim 1, wherein the inductor is an air core inductor (ACI).

9. The inductor of claim 8, wherein the ACI includes a core material that has a relative permeability close to 1.

10. The inductor of claim 1, wherein the inductor has a dielectric core that includes magnetic nano particles.

11. The inductor of claim 1, wherein the inductor is electrically coupled to a capacitor by at least one shaped via that is not part of the inductor.

12. The inductor of claim 11, wherein the capacitor is formed on a semiconductor die mounted to the package substrate. and wherein the inductor is a component in a fully integrated voltage regulator (FIVR).

13. A method of forming an inductor in a package substrate, comprising:
forming a first inductor line over a first dielectric layer;
depositing a photoresist layer over the first dielectric layer and the first inductor line;
patterning the photoresist layer to form a shaped via opening that extends along the length of the first inductor line;
depositing a conductive material into the shaped via opening to form a shaped via over the first inductor line;
removing the photoresist layer;
forming a second dielectric layer over the first dielectric layer, the first inductor line, and the shaped via, wherein a top surface of the second dielectric layer is formed above a top surface of the shaped via; and
recessing the second dielectric layer to expose a top portion of the shaped via.

14. The method of claim 13, wherein the inductor is a spiral inductor.

15. The method of claim 13, wherein the shaped via has a width that is less than a width of the first inductor line.

16. The method of claim 13, wherein the shaped via has a width that is substantially equal to a width of the first inductor line.

17. The method of claim 13, further comprising:
forming a second inductor line over the shaped via.

18. The method of claim 13, wherein recessing the second dielectric layer includes a wet etch, a dry etch, a wet blast, or a laser ablation process.

19. The method of claim 18, wherein the recessing is a laser ablation process, and wherein the recessing is only implemented proximate to the shaped via.

20. An air core inductor (ACI) formed in a package substrate comprising:
a first inductor line formed on the package substrate, wherein the first inductor line includes a plurality of turns;
a shaped via formed over the first inductor line;
a dielectric layer formed over the package substrate, the first inductor line and around the shaped via;
a second inductor line formed over the shaped via; and
a capacitor electrically coupled to the inductor, wherein the capacitor is formed on a semiconductor die mounted to the package substrate.

21. The ACI of claim 20, wherein the inductor is a component in a fully integrated voltage regulator (FIVR).

22. The ACI of claim 21, wherein the inductor is electrically coupled to the capacitor by at least one shaped via that is not part of the inductor.

23. The ACI of claim 20, wherein the dielectric layer is a photosensitive dielectric layer.

24. The ACI of claim 20, wherein the shaped via has a width that is less than a width of the first inductor line.

25. The ACI of claim 20, wherein the shaped via has a width that is substantially equal to a width of the first inductor line.
